(19) United States
(12) Patent Application Publication
(10) Pub. No.: US 2024/0263345 A1
(43) Pub. Date: Aug. 8, 2024

(54) SILICON CARBIDE CRYSTAL EXPANSION APPARATUS, SILICON CARBIDE CRYSTAL EXPANSION METHOD AND SILICON CARBIDE CRYSTAL EXPANSION PROCESS

(71) Applicant: Winsheng Material Technology (WMT) Co., Ltd., New Taipei City (TW)

(72) Inventors: Chi-Hang Hung, New Taipei City (TW); Min-Sheng Chu, New Taipei City (TW); Wei-Tse Hsu, Hsinchu County (TW); Lei Fang, New Taipei City (TW)

(73) Assignee: Winsheng Material Technology (WMT) Co., Ltd., New Taipei City (TW)

(21) Appl. No.: 18/321,756

(22) Filed: May 22, 2023

(30) Foreign Application Priority Data
Feb. 8, 2023 (TW) 112104415

(51) Int. Cl. C30B 23/06; C30B 29/36

(52) U.S. Cl. CPC C30B 23/066; C30B 29/36

(57) ABSTRACT

A silicon carbide crystal expansion apparatus includes a crucible and a heating device. The crucible includes a main body and a cover body. The main body has a raw material space suitable for placing a silicon carbide raw material. The cover body is suitable for being placed above the main body, and has an accommodating space suitable for a silicon carbide seed and a crystal expansion space located below the accommodating space. The heating device is thermally coupled to the crucible. The upper portion of the crystal expansion space has a first size, and the lower portion of the crystal expansion space has a second size, and the second size is larger than the first size.

### CROSS-REFERENCE TO RELATED APPLICATION

This application claims the priority benefit of Taiwan application serial no. 112104415, filed on Feb. 8, 2023. The entirety of the above-mentioned patent application is hereby incorporated by reference herein and made a part of this specification.

### BACKGROUND

### Technical Field

The disclosure relates to a crystal expansion apparatus, a crystal expansion method, and a crystal expansion process, and particularly relates to a silicon carbide crystal expansion apparatus, a silicon carbide crystal expansion method, and a silicon carbide crystal expansion process.

### Description of Related Art

Compared with single crystal silicon (e.g., monocrystalline silicon, monocrystalline Si), single crystal silicon carbide (e.g., monocrystalline silicon carbide, monocrystalline SiC) has a larger energy band gap. Additionally, comparing the electronic devices made by the corresponding monocrystalline (e.g., monocrystalline Si vs. monocrystalline SiC), the breakdown voltage and thermal conductivity of monocrystalline SiC are better than those of monocrystalline Si. Moreover, the carrier mobility of monocrystalline SiC is comparable to that of monocrystalline Si, and the electron saturated drift velocity of monocrystalline SiC is larger than that of monocrystalline Si. Due to these characteristics, monocrystalline SiC may be more suitable than monocrystalline Si for the application of electronic devices (e.g., a higher frequency, higher voltage, higher current and/or higher power electronic devices).

Furthermore, for a manufacturing method of a crystal (e.g., ingot or seed), the melting point of silicon carbide (about: 2,730 C) is much higher than that of silicon (about: 1,410 C). Therefore, a traditional crystal growth method (e.g., the Czochralski method) commonly used for silicon crystal may be difficult to apply to the manufacturing method of silicon carbide crystal.

### SUMMARY

The disclosure provides a silicon carbide crystal expansion apparatus, a silicon carbide crystal expansion method, a silicon carbide crystal expansion process, by which a silicon carbide crystal may be manufactured more efficiently and/or a manufactured silicon carbide crystal may have good quality.

A silicon carbide crystal expansion apparatus of the disclosure includes a crucible and a heating device. The crucible includes a main body and a cover body. The main body has a raw material space suitable for placing a silicon carbide raw material. The cover body is suitable for being placed above the main body, and has an accommodating space suitable for a silicon carbide seed and a crystal expansion space located below the accommodating space. The heating device is thermally coupled to the crucible. The upper portion of the crystal expansion space has a first size, and the lower portion of the crystal expansion space has a second size, and the second size is larger than the first size.

A silicon carbide crystal expansion method of the disclosure includes the following steps: providing the aforementioned silicon carbide crystal expansion apparatus; placing the silicon carbide raw material in the raw material space; placing a silicon carbide seed in the accommodating space; and heating the crucible by the heating device, so that the silicon carbide raw material placed in the raw material space forming a silicon carbide and being disposed on the silicon carbide seed in the accommodating space.

A silicon carbide crystal expansion process of the disclosure includes performing a plurality times of the aforementioned silicon carbide crystal expansion method for expanding a 6-inch silicon carbide seed to 8 inches.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A and FIG. 1B are a portion of cross-sectional perspective schematic drawings of a silicon carbide crystal expansion apparatus according to an embodiment of the disclosure when performing a silicon carbide crystal expansion method.

FIG. 2 is a schematic cross-sectional view of a silicon carbide seed according to an embodiment of the disclosure.

FIG. 3 is a schematic cross-sectional view of a morphology after expanding a silicon carbide seed according to an embodiment of the disclosure.

FIG. 4 is a schematic cross-sectional view of a method of forming an expanded silicon carbide seed according to an embodiment of the disclosure.

FIG. 5 is a portion of a flow chart of a silicon carbide crystal expansion process according to an embodiment of the disclosure.

FIG. 6A and FIG. 6B are schematic drawings of a thermal field simulation of a silicon carbide crystal expansion apparatus according to an experimental embodiment of the disclosure.

FIG. 7A and FIG. 7B are schematic drawings of a thermal field simulation of a silicon carbide crystal expansion apparatus according to an experimental embodiment of the disclosure.

FIG. 8A and FIG. 8B are schematic drawings of a thermal field simulation of a silicon carbide crystal expansion apparatus according to an experimental embodiment of the disclosure.

FIG. 9A and FIG. 9B are schematic drawings of a thermal field simulation of a silicon carbide crystal expansion apparatus according to an experimental embodiment of the disclosure.

FIG. 10A and FIG. 10B are schematic drawings of a thermal field simulation of a silicon carbide crystal expansion apparatus according to an experimental embodiment of the disclosure.

### DESCRIPTION OF THE EMBODIMENTS

Reference will now be made in detail to the present preferred embodiments of the disclosure, examples of which are illustrated in the accompanying drawings. As those skilled in the art would realize, the described embodiments may be modified in various different ways without departing from the spirit or scope of the disclosure.

In the drawings, a thickness or a size of each element, etc., is exaggerated for claritys sake. The exemplary embodiment is described below with reference of a cross-sectional view of a schematic diagram of an idealized embodiment. Therefore, a shape change of the figure serving as a result of manufacturing techniques and/or tolerances may be expected. Therefore, the embodiment of the disclosure should not be construed as limited to a particular shape of a region as shown herein, but includes a shape deviation caused by manufacturing tolerance. For example, a shown acute angle may be round. Therefore, a region shown in the figure is essentially schematic, and a shape thereof is not intended to show an accurate shape of the region, and is not intended to limit a range of the claims of the disclosure. Moreover, in order to clearly show the directional relationship between different drawings, the corresponding directions are represented by a Cartesian coordinate system (that is, an XYZ/xyz rectangular coordinate system) in some drawings.

Throughout the specification, the same reference numerals denote the same elements.

The terminology used herein is for the purpose of describing particular embodiments and is not intended to be limiting of the disclosure. As used herein, the singular forms “a,” “an” and “the” are intended to include the plural forms as well, unless the context clearly indicates otherwise. In addition, relative terms such as under or bottom and above or top may be used for describing a relationship of one element and another element as that shown in the figures.

The term substantial, about, approximately, roughly or other similar terms used herein include the related value and an average within an acceptable deviation range for a specific value determined by those skilled in the art, considering a discussed measurement, a specific number of errors related to the measurement (i.e. a limitation of a measuring system), or a calculation error caused by some factors, such as the number of digits used in the calculation or conversion process, rounding number up or down, unit conversion (e.g., 1 inch is about 25.4 millimeters), or error propagation, etc.

### <Silicon Carbide Crystal Expansion Apparatus>

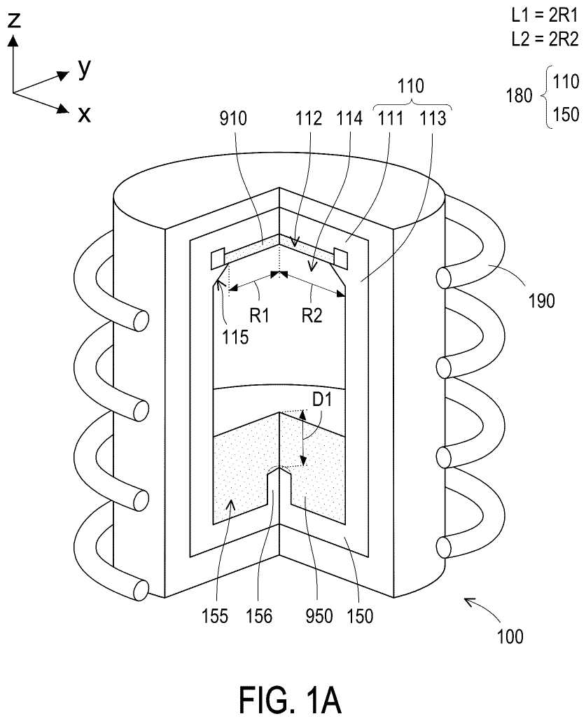

FIG. 1A and FIG. 1B are a portion of cross-sectional perspective schematic drawings of a silicon carbide crystal expansion apparatus according to an embodiment of the disclosure when performing a silicon carbide crystal expansion method. For example, FIG. 1A and/or FIG. 1B may be a partial sectional schematic drawing of a fan-shaped section outward from the center of the outer circular contour corresponding to a raw material space 155, an accommodating space 112 or a crystal expansion space 114 of the silicon carbide crystal expansion apparatus 100.

Referring FIG. 1A and/or FIG. 1B, the silicon carbide crystal expansion apparatus 100 includes a crucible 180 and a heating device 190. The heating device 190 is thermally coupled to the crucible 180, so as to be suitable for heating the crucible 180 and/or a material placed therein. In the embodiment, the heating device 190 may include a coil (e.g., an electric heating coil or an induction coil), but the disclosure is not limited thereto. In an embodiment not shown, the heating device 190 may include, for example, an infrared heater.

The crucible 180 includes a main body 150 and a cover body 110. The main body 150 has a raw material space 155 suitable for placing a silicon carbide raw material 950. The cover body 110 is adapted to be placed above the main body 150. The cover body 110 has an accommodating space 112 and a crystal expansion space 114 below the accommodating space 112. The accommodating space 112 is suitable for placing a silicon carbide seed 910.

It should be noted that the disclosure does not limit the main body 150 and/or the cover body 110 to be a single component. That is, the main body 150 and/or the cover body 110 may be a single component; or, the main body 150 and/or the cover body 110 may be an assembly, integration, combination or association of multiple components. In other words, a body having a corresponding raw material space 155 in which the silicon carbide raw material 950 could be placed may be referred as a main body (e.g., the main body 150); and/or a body having a corresponding accommodating space 112 and a crystal expansion space 114 and being suitable for placing a silicon carbide seed 910 therein for crystal expansion may be referred as a cover body (e.g., the cover body 110). For example, the cover body 110 may include an upper cover 111 and a lower cover 113.

In the embodiment, as a view from a direction parallel to a top view direction (e.g., the −z direction), an outer contour of the raw material space 155, the accommodating space 112 or the crystal expansion space 114 may be substantially circular.

In the embodiment, the top of the crystal expansion space 114 (e.g., a place where the crystal expansion space 114 is close to the accommodating space 112) has a first size L1, the bottom of the crystal expansion space 114 (e.g., a place where the crystal expansion space 114 is far away from the accommodating space 112) has a second size L2, and the second size L2 is larger than the first size L1. In this way, it is suitable to perform a corresponding crystal expansion step with the silicon carbide seed 910 placed in the accommodating space 112.

In the embodiment, as a view from a direction parallel to a top view direction (e.g., the −z direction), an outer contour of the crystal expansion space 114 may be substantially circular. That is, on a section (e.g., a section parallel to the x-y plane) perpendicular to the aforementioned direction, an outline of the sidewall 115 of the crystal expansion space 114 may be substantially circular. Additionally, on another section (e.g., a section parallel to the x-z or y-z plane) parallel to the aforementioned direction, the sidewall 115 of the crystal expansion space 114 may be an oblique plane. That is, the sidewall 115 of the crystal expansion space 114 may be an arc slope. As such, the crystal expansion space 114 is suitable for performing a gradually crystal expansion step to improve the quality or yield of an expanding crystal.

In the embodiment, the first size L1 may be the diameter (e.g., two times of the radius R1) of the outer circular contour corresponding to the top of the crystal expansion space 114, and the second size L2 may be the diameter (e.g., two times of the radius R2) of the outer circular contour corresponding to the bottom of the crystal expansion space 114.

In an embodiment, the first size L1 is about 6 inches or 150 mm (millimeter); or larger than 6 inches or 150 mm. That is, the silicon carbide crystal expansion apparatus 100 may be adapted to perform a crystal expansion step from a silicon carbide seed 910 with a diameter of about 6 inches or 150 mm; or larger than 6 inches or 150 mm.

In an embodiment, the second size L2 is about 8 inches or 200 mm; or, smaller than 8 inches or 200 mm. That is, the silicon carbide crystal expansion apparatus 100 may be adapted to perform a crystal expansion step to produce a silicon carbide seed with a diameter of about 8 inches or 200 mm; or, smaller than 8 inches or 200 mm.

In an embodiment, the difference between the second size L2 and the first size L1 (e.g., L2−L1) may be referred as an expanded size, and the expanded size is about 0.4 inches or 10 mm.

In an embodiment, under a same unit of the expanded thickness H1 and the expanded size, the ratio of expanded thickness H1 to expanded size (e.g., H1/(L2−L1)) is about ¾˜ 5/4. That is, on another section parallel to the aforementioned direction, the slope of the sidewall 115 of the crystal expansion space 114 may be about ¾˜ 5/4. As such, the crystal expansion space 114 is suitable for performing a gradually crystal expansion step to improve the quality or yield of an expanding crystal. If the slope of the sidewall of the crystal expansion space is too low, the risk of lattice mismatch may increase during the crystal expansion step (e.g., a polycrystalline may be formed). If the slope of the sidewall of the crystal expansion space is too high, the efficiency of the crystal expansion step may be reduced.

In the embodiment, a material of the crucible 180 may include graphite. For example, a material forming the raw material space 155, the accommodating space 112 and the crystal expansion space 114 of the crucible 180 may at least include graphite. Graphite is a form of the element carbon. As such, the possibility of elemental contamination may be reduced during the crystal expansion step. In an embodiment, the crucible 180 is a graphite crucible.

In the embodiment, the main body 150 includes at least one heat-conductive rod 156 extending upward from the bottom of the raw material space 155. When heating the silicon carbide raw material 950 placed in the raw material space 155, the distribution of thermal field of the silicon carbide raw material 950 may be relatively uniform by the heat conduction of the heat-conductive rod 156, so as the quality or yield of an expanding crystal may be further improved. In the embodiment, the heat-conductive rod 156 may be a graphite heat-conductive rod.

In an embodiment, the height of the heat-conductive rod 156 (e.g., the size on the extension direction of the heat-conductive rod 156) may be about 50 mm˜120 mm. In the embodiment, as a view from a direction parallel to a top view direction (e.g., the −z direction), the position of the heat-conductive rod 156 in the main body 150 is symmetrical. As such, the thermal field in the main body 150 may be made more uniform. Taking FIG. 1A or FIG. 1B as an example, the outline of the main body 150 may be circular in the top view direction, and the position of the heat-conductive rod 156 is roughly located at the center of the aforementioned circle.

In FIG. 1A or FIG. 1B, only one heat-conductive rod 156 is schematically shown in the main body 150, but the disclosure is not limited thereto. In an embodiment not shown, the main body 150 may include a plurality of heat-conductive rods that are the same as or similar to heat-conductive rod 156. In an embodiment not shown, as a view from a direction parallel to a top view direction (e.g., the −z direction), the positions of the plurality of heat-conductive rods in the main body 150 are symmetrical. Taking two heat-conducting rods as example, as a view from a direction parallel to a top view direction (e.g., the −z direction), the outline of the main body 150 may be circular, and the position of the midpoint of the two heat-conductive rods is roughly located at the center of the aforementioned circle. Taking three heat-conducting rods as example, as a view from a direction parallel to a top view direction (e.g., the −z direction), the outline of the main body 150 may be circular, the positions of the three heat-conductive rods may form an equilateral triangle, and the midpoint of the aforementioned equilateral triangle is roughly located at the center of the aforementioned circle. Taking four heat-conducting rods as example, as a view from a direction parallel to a top view direction (e.g., the −z direction), the outline of the main body 150 may be circular, the positions of four heat-conductive rods may form a square, and the midpoint of the aforementioned square is roughly located at the center of the aforementioned circle.

In an embodiment, in a direction (e.g., a direction parallel to the x-y plane) perpendicular to the extension direction (e.g., +z direction) of the heat-conductive rod 156, the distance between the heat-conductive rod 156 and the inner edge of the main body 150 is less than or equal to 10 centimeters (cm). As such, the heating efficiency and/or heating uniformity of the silicon carbide raw material 950 placed in the main body 150 may be improved.

In an embodiment not shown, if the main body 150 includes a plurality of heat-conductive rods that are the same as or similar to the heat-conductive rod 156, the distance between two adjacent heat-conductive rods may be less than or equal to 10 cm.

In an embodiment, in a direction (e.g., a direction parallel to the x-y plane) perpendicular to the extension direction (e.g., +z direction) of the heat-conductive rod 156, the distance between the heat-conductive rod 156 and the inner edge of the main body 150 is greater than or equal to 3 cm. As such, the amount of the silicon carbide raw material 950 placed in the main body 150 may be more efficient.

In an embodiment not shown, if the main body 150 includes a plurality of heat-conductive rods that are the same as or similar to the heat-conductive rod 156, the distance between two adjacent heat-conductive rods may be greater than or equal to 3 cm.

### <Crystal Expansion Method of Silicon Carbide Crystal>

Referring to FIG. 1A, FIG. 1B and FIG. 2 to FIG. 4, in the embodiment, the silicon carbide crystal expansion method could be described in detail as follows.

The silicon carbide crystal expansion apparatus 100 is suitable for performing the silicon carbide crystal expansion process or step. Therefore, in the subsequent description, the silicon carbide crystal expansion apparatus 100 is used as an example, and the elements, components, devices, and/or corresponding symbols thereof are used. But it should be noted that the disclosure is not limited to the use of the silicon carbide crystal expansion apparatus 100. In an embodiment not shown, a silicon carbide crystal expansion apparatus that is similar to the silicon carbide crystal expansion apparatus 100 may be used for performing the silicon carbide crystal expansion process or step.

Referring to FIG. 1A, a silicon carbide (SiC) raw material 950 is placed in the raw material space 155. In the embodiment, the silicon carbide raw material 950 may be or includes, for example, silicon carbide powder.

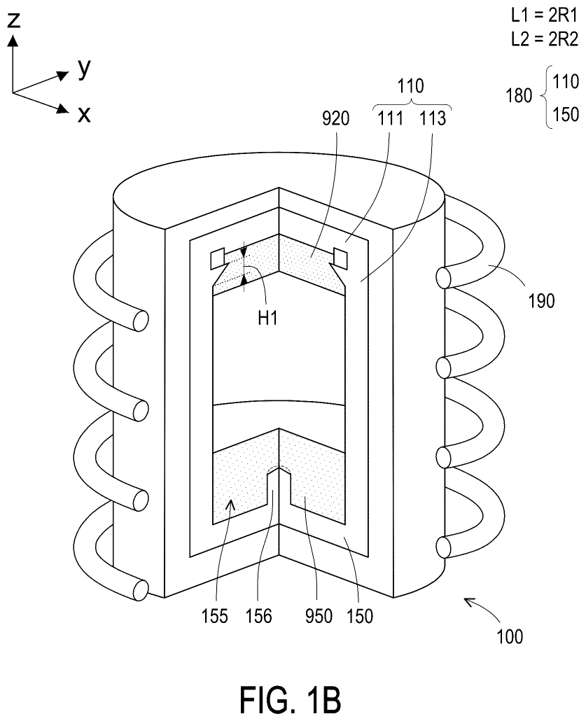

Referring to FIG. 1A and FIG. 2, a silicon carbide seed 910 is placed in the accommodating space 112.

For example, the cover body 110 may include an upper cover 111 and a lower cover 113. The upper cover 111 and the lower cover 113 may form the accommodating space 112. The crystal expansion space 114 may be located corresponding to the lower cover 113. The size L3 (e.g. diameter) of the silicon carbide seed 910 may be slightly larger than the first size L1. The silicon carbide seed 910 may be placed on the lower cover 113 and completely covers the top of the crystal expansion space 114; then, after the upper cover 111 and the lower cover 113 are combined, the silicon carbide seed 910 may be fixed in the accommodating space 112.

In an embodiment, before the silicon carbide raw material 950 placed in the crucible 180 being heated, the minimum distance between the top surface of the silicon carbide raw material 950 placed in the crucible 180 and the top of the heat-conductive rod 156 (if any, but not limited) is less than or equal to 10 cm.

Referring to FIG. 1A to FIG. 1B, the crucible 180 is heated by the heating device 190, so that the silicon carbide raw material 950 placed in the raw material space 155 could be sublimated, and the silicon carbide could be deposited on the silicon carbide seed 910 placed in the accommodating space 112. In an embodiment, a deposition method by heating the solid powder (e.g., the silicon carbide raw material 950) to generate corresponding gas molecules, and then cooling and be deposited on a corresponding (e.g., the silicon carbide seed 910) could be referred as a physical vapor transport method (PVT method) or a sublimation method.

In an embodiment, the main body 150 includes a heat-conductive rod 156, and the silicon carbide raw material 950 placed in the raw material space 155 completely covers the top of the heat-conductive rod 156 before the crystal expansion step or before enabling the heating device 190 for heating the silicon carbide raw material 950 placed in the raw material space 155. In an embodiment, the distance D1 (as shown in FIG. 1A) between the top surface of the silicon carbide raw material 950 placed in the raw material space 155 and the top of the heat-conductive rod 156 is greater than the corresponding expanded thickness H1 (as shown in FIG. 1B). As such, during the crystal expansion step (e.g., the silicon carbide raw material 950 placed in the raw material space 155 being heat and sublimated, and the silicon carbide being deposited on the silicon carbide seed 910 placed in the accommodating space 112), the possibility of the heat-conductive rod 156 being exposed from the silicon carbide raw material 950 may be reduced, and/or the distribution of the corresponding gas molecules produced by the silicon carbide raw material 950 after heating may be more uniform, which could improve the quality or yield of an expanding crystal.

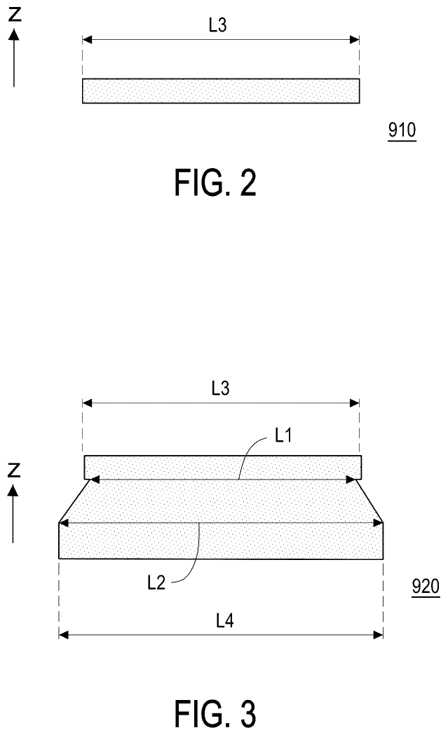

Referring to FIG. 1B and FIG. 3, the morphology after expanding the silicon carbide seed 910 (as shown in FIG. 2) could be as shown in FIG. 3 (e.g., an expanded silicon carbide seed 920).

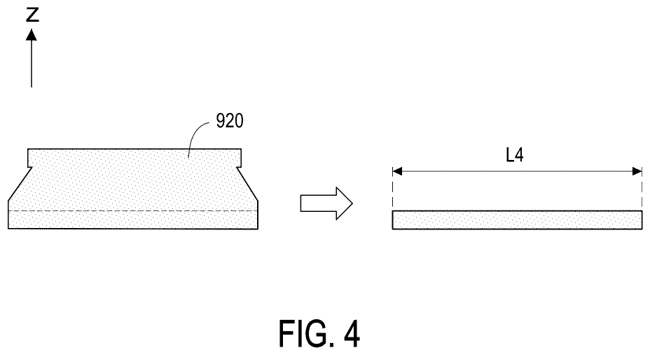

Referring to FIG. 4, the expanded silicon carbide seed 920 could be cut properly to form another silicon carbide seed silicon carbide seed 930 with a larger size. That is, the size L4 of the silicon carbide seed 930 is larger than the size L3 of the silicon carbide seed 910. For example, the diameter of the silicon carbide seed 930 is larger than the diameter of the silicon carbide seed 910.

In an embodiment, another portion of the cut expanded silicon carbide seed 920 (e.g., a silicon carbide seed of the expanded silicon carbide seed 920 being cut) may be processed appropriately to form a silicon carbide seed with the same size or similar size as the silicon carbide seed 910. As such, a silicon carbide seed with a size same as or similar to the silicon carbide seed 910 may be used for performing a corresponding crystal expansion step, and the silicon carbide seed 930 may be used for performing another corresponding crystal expansion step. As such, the throughput of producing a silicon carbide seed and the utilization rate of a corresponding apparatus/equipment could be increased.

In an embodiment, another silicon carbide seed (e.g., the silicon carbide seed 930; or, a silicon carbide seed with a size larger than the silicon carbide seed 930) may be used for performing a corresponding crystal expansion step same as or similar to the aforementioned crystal expansion step by a corresponding silicon carbide crystal expansion apparatus (e.g., a silicon carbide crystal expansion apparatus similar to the silicon carbide crystal expansion apparatus 100 but having a larger size of accommodating space and crystal expansion space). In an embodiment, the aforementioned another silicon carbide seed may be suitable for the manufacture of silicon carbide ingot.

In an embodiment, during the crystal expansion step, the pressure in the crucible 180 may be about 0.5 torr to 30 torr.

In an embodiment, during the crystal expansion step, the temperature inside the crucible 180 may be about 2000C˜2500C.

In an embodiment, during the crystal expansion step, the temperature gradient of the silicon carbide raw material 950 (e.g., the difference between the highest temperature and the lowest temperature in the silicon carbide raw material 950) placed in the raw material space 155 may be less than or equal to 15 C.

In an embodiment, during the crystal expansion step, the deposition rate of the silicon carbide (e.g., silicon carbide on the silicon carbide seed) may be about 100˜200 microns/hour (m/hr).

In an embodiment, during the crystal expansion step, the pressure in the crucible 180 may be about 0.5 torr to 30 torr, the temperature inside the crucible 180 may be about 2000C˜2500C, the temperature gradient of the silicon carbide raw material 950 placed in the raw material space 155 may be less than or equal to 15 C, and the deposition rate of the silicon carbide may be about 100 m/hr˜200 m/hr. As such, the quality or yield of an expanding crystal may be improved.

### <Silicon Carbide Crystal Expansion Process>

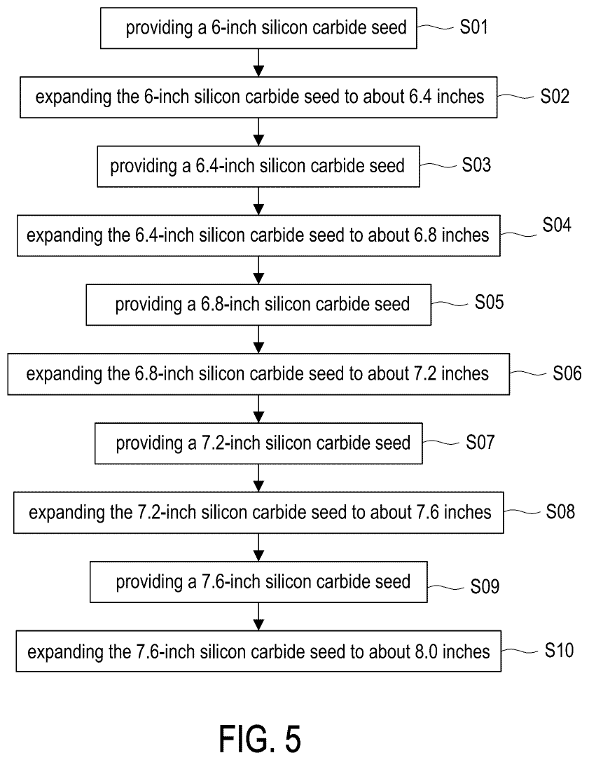

Referring to FIG. 5 a silicon carbide crystal expansion process may include the following steps in sequence: step S01: providing a 6-inch silicon carbide seed; step S02: expanding the 6-inch silicon carbide seed to about 6.4 inches; step S03: providing a 6.4-inch silicon carbide seed; step S04: expanding the 6.4-inch silicon carbide seed to about 6.8 inches; step S05: providing a 6.8-inch silicon carbide seed; step S06: expanding the 6.8-inch silicon carbide seed to about 7.2 inches; step S07: providing a 7.2-inch silicon carbide seed; step S08: expanding the 7.2-inch silicon carbide seed to about 7.6 inches; step S09: providing a 7.6-inch silicon carbide seed; and step S10: expanding the 7.6-inch silicon carbide seed to about 8.0 inches.

For example, a silicon carbide seed of about 6.0 inches/150 mm could be expanded to about 6.4 inches/160 mm by the same or similar step as shown in FIG. 1A to FIG. 1B with the corresponding descriptions. Additionally, the seed expanded from the 6-inch/150 mm silicon carbide seed could be cut to form a silicon carbide seed of about 6.4 inches/160 mm by the same or similar step as shown in FIG. 4 with the corresponding descriptions. Similar to the above descriptions, a corresponding crystal expansion step and cutting step could be further performed to form a silicon carbide seed of about 6.8 inches/170 mm, a silicon carbide seed of about 7.2 inches/180 mm, a silicon carbide seed of about 7.6 inches/190 mm, or a silicon carbide seed of about 8.0 inches/200 mm.

For more example, similar to the above descriptions, a seed expanded from the 6.0 inches/150 mm silicon carbide seed may be cut to form a silicon carbide seed of about 6.4 inches/160 mm and a silicon carbide seed of about 6.0 inches/150 mm. The 6.4 inches/160 mm silicon carbide seed formed by cutting may be used for performing a corresponding crystal expansion step, and the 6.0 inches/150 mm silicon carbide seed formed by cutting may be used for performing another corresponding crystal expansion step. As such, the throughput of producing a silicon carbide seed and the utilization rate of a corresponding apparatus/equipment could be increased.

Similar to the above descriptions, a seed expanded from the 6.4 inches/160 mm silicon carbide seed may be cut to form a silicon carbide seed of about 6.8 inches/170 mm; or further, to form a silicon carbide seed of about 6.4 inches/160 mm.

Similar to the above descriptions, a seed expanded from the 6.8 inches/170 mm silicon carbide seed may be cut to form a silicon carbide seed of about 7.2 inches/180 mm; or further, to form a silicon carbide seed of about 6.8 inches/170 mm.

Similar to the above descriptions, a seed expanded from the 7.2 inches/180 mm silicon carbide seed may be cut to form a silicon carbide seed of about 7.6 inches/190 mm; or further, to form a silicon carbide seed of about 7.2 inches/180 mm.

Similar to the above descriptions, a seed expanded from the 7.6 inches/190 mm silicon carbide seed may be cut to form a silicon carbide seed of about 8.0 inches/200 mm; or further, to form a silicon carbide seed of about 7.6 inches/190 mm.

In the process of performing the aforementioned PVT method or sublimation method, the corresponding gas molecules would be distributed in the corresponding space, and may be attached and deposited on the corresponding object surface; as such, it is more difficult to monitor the process quality of the crystal in real time (e.g., confirming whether there is lattice dislocation instantly) by an observation port (e.g.: a quartz window) or an observer (e.g.: a camera and/or a video) in the process similar to silicon crystal production. Therefore, when a silicon carbide crystal is manufactured by the aforementioned PVT method or sublimation method, the silicon carbide crystal expansion apparatus, the silicon carbide crystal expansion method and/or the silicon carbide crystal expansion process of an embodiment could be used to manufacture the silicon carbide crystal efficiently, and has a good quality.

### <Results of Thermal Field Simulation>

In a certain semiconductor process or apparatus/equipment, the thermal field analysis of the corresponding apparatus/equipment could be carried out by an infrared thermal imager. However, during the crystal expansion step by the aforementioned PVT method or sublimation method, it may be difficult to obtain a corresponding thermal field image/video by a general infrared thermal imager due to the limitation of the physical limitation of the aforementioned method. Therefore, a thermal field simulation analysis of the silicon carbide crystal expansion apparatus or a portion thereof suitable for silicon carbide crystal expansion could be performed by using a general thermal simulation analysis software (e.g., Ansys, but not limited).

In the thermal field simulation schematic drawings, different gray scales represent different temperatures, wherein according to the order of gray scale depth, a darker color is a position with a higher temperature or a higher induction heating temperature; otherwise, a lighter color is a position with a lower temperature or a lower induction heating temperature. Additionally, a thicker line is the object edge or the object boundary of the silicon carbide crystal expansion apparatus or a portion thereof, and a thinner line is a corresponding isotherm. And, in order to be consistent, a heating temperature, a corresponding height of the silicon carbide raw material and a corresponding thermal conductivity (approximately: 280 W/m K to 347 W/m K, the value may vary slightly depending on the type, doping concentration and/or density) of the silicon carbide raw material in each thermal field simulation schematic drawing are set to be the same. Moreover, a temperature gradient may be judged by the density of isotherms or the distance therebetween, so that the uniformity of the thermal field may be further judged.

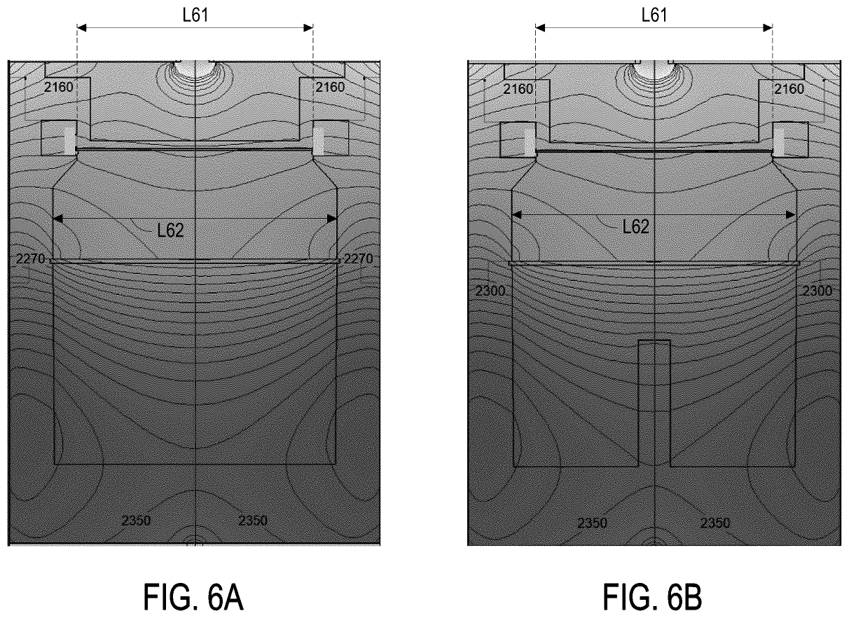

FIG. 6A and FIG. 6B are schematic drawings of a thermal field simulation of a silicon carbide crystal expansion apparatus according to an experimental embodiment of the disclosure. In particular, FIG. 6A and FIG. 6B are schematic drawings of a thermal field simulation of the crucible of the silicon carbide crystal expansion apparatus, wherein the top of the crystal expansion space has a first size (about: 6.0 inches/150 mm) L61, the bottom of the crystal expansion space has a second size (about: 6.4 inches/160 mm) L62, and the second size L62 is larger than the first size L61. Moreover, the silicon carbide crystal expansion apparatus as shown in FIG. 6A or FIG. 6B is(are) suitable for performing the silicon carbide crystal expansion process or step from about 6.0 inches/150 mm to about 6.4 inches/160 mm.

The crucible as shown in FIG. 6A is similar to the crucible as shown in FIG. 6B, the difference is that: the main body of the crucible as shown in FIG. 6B further includes a heat-conductive rod extending upward from the bottom of the raw material space. Additionally, as shown in the comparison between the thermal field of FIG. 6A and the thermal field of FIG. 6B, the uniformity of the thermal field as shown in FIG. 6B is better. However, it should be noted that the disclosure does not exclude the application of the crucible as shown in FIG. 6A for performing the silicon carbide crystal expansion process or step.

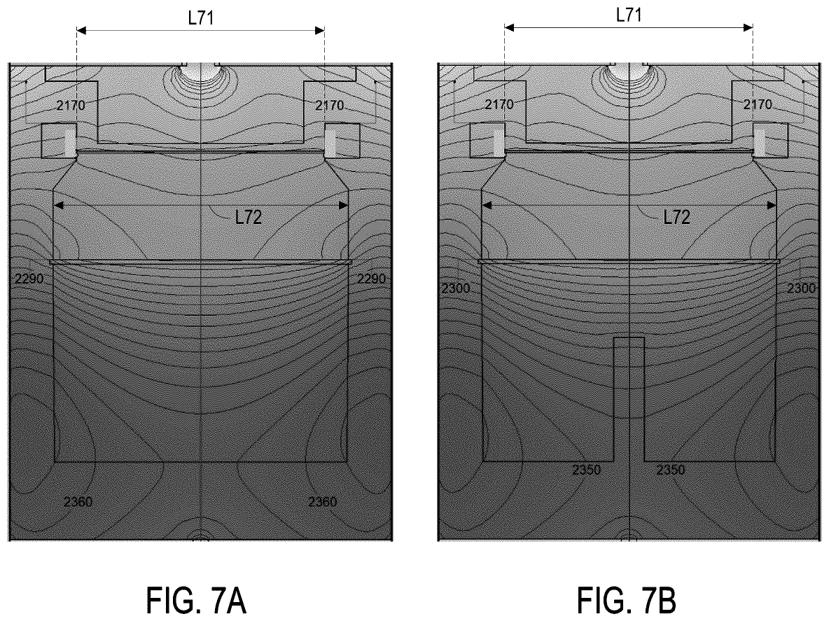

FIG. 7A and FIG. 7B are schematic drawings of a thermal field simulation of a silicon carbide crystal expansion apparatus according to an experimental embodiment of the disclosure. In particular, FIG. 7A and FIG. 7B are schematic drawings of a thermal field simulation of the crucible of the silicon carbide crystal expansion apparatus, wherein the top of the crystal expansion space has a first size (about: 6.4 inches/160 mm) L71, the bottom of the crystal expansion space has a second size (about: 6.8 inches/170 mm) L72, and the second size L72 is larger than the first size L71. Moreover, the silicon carbide crystal expansion apparatus as shown in FIG. 7A or FIG. 7B is(are) suitable for performing the silicon carbide crystal expansion process or step from about 6.4 inches/160 mm to about 6.8 inches/170 mm.

The crucible as shown in FIG. 7A is similar to the crucible as shown in FIG. 7B, the difference is that: the main body of the crucible as shown in FIG. 7B further includes a heat-conductive rod extending upward from the bottom of the raw material space. Additionally, as shown in the comparison between the thermal field of FIG. 7A and the thermal field of FIG. 7B, the uniformity of the thermal field as shown in FIG. 7B is better. However, it should be noted that the disclosure does not exclude the application of the crucible as shown in FIG. 7A for performing the silicon carbide crystal expansion process or step.

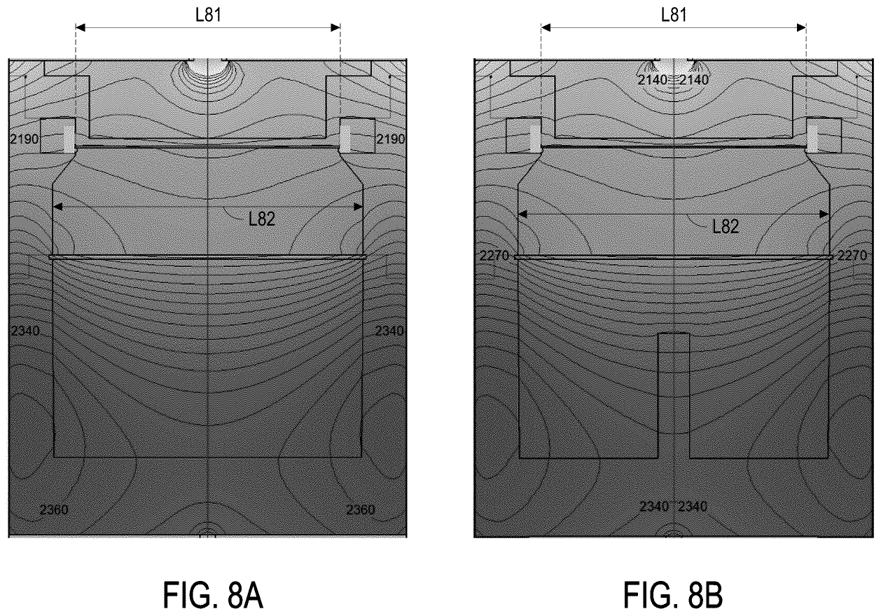

FIG. 8A and FIG. 8B are schematic drawings of a thermal field simulation of a silicon carbide crystal expansion apparatus according to an experimental embodiment of the disclosure. In particular, FIG. 8A and FIG. 8B are schematic drawings of a thermal field simulation of the crucible of the silicon carbide crystal expansion apparatus, wherein the top of the crystal expansion space has a first size (about: 6.8 inches/170 mm) L81, the bottom of the crystal expansion space has a second size (about: 7.2 inches/180 mm) L82, and the second size L82 is larger than the first size L81. Moreover, the silicon carbide crystal expansion apparatus as shown in FIG. 8A or FIG. 8B is(are) suitable for performing the silicon carbide crystal expansion process or step from about 6.8 inches/170 mm to about 7.2 inches/180 mm.

The crucible as shown in FIG. 8A is similar to the crucible as shown in FIG. 8B, the difference is that: the main body of the crucible as shown in FIG. 8B further includes a heat-conductive rod extending upward from the bottom of the raw material space. Additionally, as shown in the comparison between the thermal field of FIG. 8A and the thermal field of FIG. 8B, the uniformity of the thermal field as shown in FIG. 8B is better. However, it should be noted that the disclosure does not exclude the application of the crucible as shown in FIG. 8A for performing the silicon carbide crystal expansion process or step.

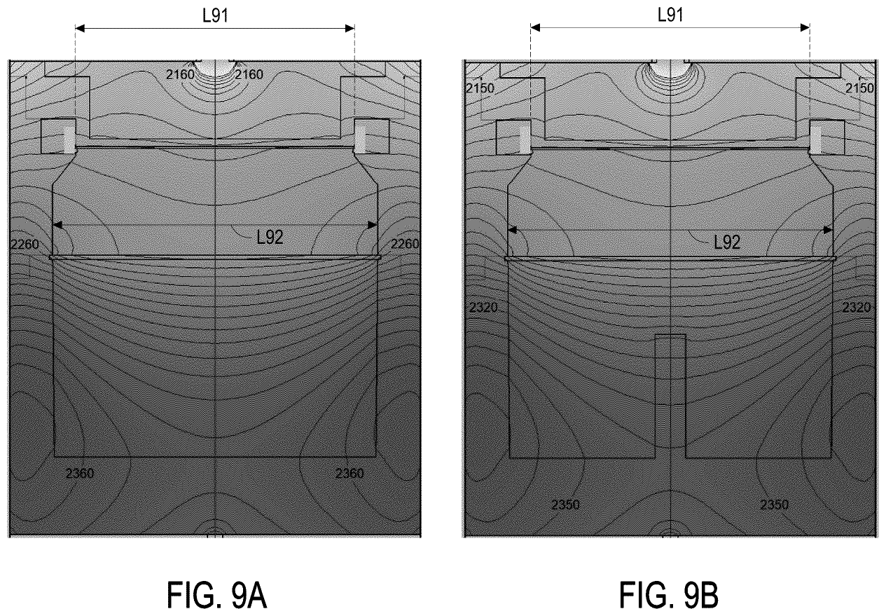

FIG. 9A and FIG. 9B are schematic drawings of a thermal field simulation of a silicon carbide crystal expansion apparatus according to an experimental embodiment of the disclosure. In particular, FIG. 9A and FIG. 9B are schematic drawings of a thermal field simulation of the crucible of the silicon carbide crystal expansion apparatus, wherein the top of the crystal expansion space has a first size (about: 7.2 inches/180 mm) L91, the bottom of the crystal expansion space has a second size (about: 7.6 inches/190 mm) L92, and the second size L92 is larger than the first size L91. Moreover, the silicon carbide crystal expansion apparatus as shown in FIG. 9A or FIG. 9B is(are) suitable for performing the silicon carbide crystal expansion process or step from about 7.2 inches/180 mm to about 7.6 inches/190 mm.

The crucible as shown in FIG. 9A is similar to the crucible as shown in FIG. 9B, the difference is that: the main body of the crucible as shown in FIG. 9B further includes a heat-conductive rod extending upward from the bottom of the raw material space. Additionally, as shown in the comparison between the thermal field of FIG. 9A and the thermal field of FIG. 9B, the uniformity of the thermal field as shown in FIG. 9B is better. However, it should be noted that the disclosure does not exclude the application of the crucible as shown in FIG. 9A for performing the silicon carbide crystal expansion process or step.

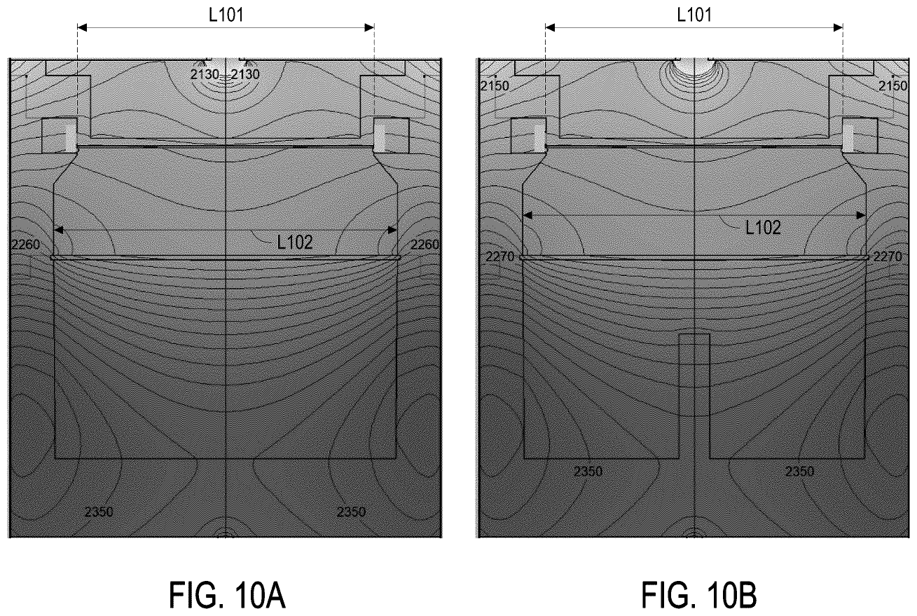

FIG. 10A and FIG. 10B are schematic drawings of a thermal field simulation of a silicon carbide crystal expansion apparatus according to an experimental embodiment of the disclosure. In particular, FIG. 10A and FIG. 10B are schematic drawings of a thermal field simulation of the crucible of the silicon carbide crystal expansion apparatus, wherein the top of the crystal expansion space has a first size (about: 7.6 inches/190 mm) L101, the bottom of the crystal expansion space has a second size (about: 8.0 inches/200 mm) L102, and the second size L102 is larger than the first size L101. Moreover, the silicon carbide crystal expansion apparatus as shown in FIG. 10A or FIG. 10B is(are) suitable for performing the silicon carbide crystal expansion process or step from about 7.6 inches/190 mm to about 8.0 inches/200 mm.

The crucible as shown in FIG. 10A is similar to the crucible as shown in FIG. 10B, the difference is that: the main body of the crucible as shown in FIG. 10B further includes a heat-conductive rod extending upward from the bottom of the raw material space. Additionally, as shown in the comparison between the thermal field of FIG. 10A and the thermal field of FIG. 10B, the uniformity of the thermal field as shown in FIG. 10B is better. However, it should be noted that the disclosure does not exclude the application of the crucible as shown in FIG. 10A for performing the silicon carbide crystal expansion process or step.

### <Silicon Carbide Crystal Expansion Apparatus Including Crucible Set>

In an embodiment, a silicon carbide crystal expansion apparatus may include a plurality of crucibles the same as or similar to the crucible 180 and at least one heating device the same as or similar to the heating device 190. That is, the plurality of crucibles could be referred as a crucible set, and/or the silicon carbide crystal expansion apparatus including the plurality of crucibles could be referred as a silicon carbide crystal expansion apparatus including crucible set.

In an embodiment, each crucible of the crucible set may have a different size.

In an embodiment, the crystal expansion space corresponding to each crucible of the crucible set may have different sizes. For example, the first size corresponding to each crucible of the crucible set is different from each other, and/or the second size corresponding to each crucible of the crucible set is different from each other.

In an embodiment, a silicon carbide crystal expansion apparatus may include at least two crucibles. One of the aforementioned two crucibles has a smaller size, another one of the aforementioned two crucibles has a larger size, the second size of the crucible having a smaller size is about equal to the first size of the crucible having a larger size.

In an embodiment, a silicon carbide crystal expansion apparatus may include five crucibles. One of the aforementioned five crucibles may be the same as or similar to the crucible as shown in FIG. 6A or 6B, that is, the first size and the second size thereof is about 6.0 inches/150 mm and 6.4 inches/160 mm respectively; one of the aforementioned five crucibles may be the same as or similar to the crucible as shown in FIG. 7A or 7B, that is, the first size and the second size thereof is about 6.4 inches/160 mm and 6.8 inches/170 mm respectively; one of the aforementioned five crucibles may be the same as or similar to the crucible as shown in FIG. 8A or 8B, that is, the first size and the second size thereof is about 6.8 inches/170 mm and 7.2 inches/180 mm respectively; one of the aforementioned five crucibles may be the same as or similar to the crucible as shown in FIG. 9A or 9B, that is, the first size and the second size thereof is about 7.2 inches/180 mm and 7.6 inches/190 mm respectively; and one of the aforementioned five crucibles may be the same as or similar to the crucible as shown in FIG. 10A or 10B, that is, the first size and the second size thereof is about 7.6 inches/190 mm and 8.0 inches/200 mm respectively.

In an embodiment, the silicon carbide crystal expansion apparatus including crucible set may include one heating device. The aforementioned heating device is suitable for heating the plurality of crucibles having different size.

In an embodiment, the silicon carbide crystal expansion apparatus including crucible set may include a plurality of heating devices. At least one of the aforementioned heating devices may be suitable for heating more than one of the plurality of crucibles having different size.

### EXPERIMENTAL EXAMPLE

The experimental examples as shown below could be used as a concrete explanation of the disclosure. An embodiment of the disclosure may include the following experimental example, but the embodiment of the disclosure is not limited by the following experimental example.

In the following experimental example, a silicon carbide crystal expansion process or step may be performed by a silicon carbide crystal expansion apparatus of aforementioned embodiment (e.g., the same as or similar to the silicon carbide crystal expansion apparatus as shown in FIG. 1A and/or FIG. 1B), and/or by a silicon carbide crystal expansion process or step of aforementioned embodiment (e.g., the same as or similar to the silicon carbide crystal expansion process or step as shown in FIG. 1A to FIG. 1B). The difference between the different experimental examples is that the sidewall of the crystal expansion space has different slopes. For clear comparison, the corresponding results are described in the [Table 1].

TABLE 1

| Experimental | | |
|---|---|---|
| example | Slope | Experimental result |
| 1 | ½ | Poor. It is easy to produce a polycrystalline structure, which |
| | | may be caused by a small slope value. |
| 2 | ¾ | Good. Silicon carbide single crystal grows stably and produces |
| | | a single crystal structure (without polycrystalline structure). |
| 3 | 1 | Good. Silicon carbide single crystal grows stably and produces |
| | | a single crystal structure (without polycrystalline structure). |
| 4 | 5/4 | Normal. Lower crystal expansion efficiency but still produces |
| | | a single crystal structure (without polycrystalline structure). |
| 5 | 4/3 | Poor. Poor crystal expansion efficiency, which may be caused |
| | | by a high slope value. |
| 6 | 3/2 | Very poor. Very poor crystal expansion efficiency, which may |
| | | be caused by a high slope value. |

Based on the above, a silicon carbide crystal may be manufactured more efficiently and/or a manufactured silicon carbide crystal may have good quality via using a silicon carbide crystal expansion apparatus, a silicon carbide crystal expansion method, a silicon carbide crystal expansion process of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A silicon carbide crystal expansion apparatus, comprising:
a crucible, comprising:
a main body, having a raw material space suitable for placing a silicon carbide raw material; and
a cover body, adapted to be placed above the main body, wherein the cover body has an accommodating space and a crystal expansion space below the accommodating space, a top of the crystal expansion space has a first size, a bottom of the crystal expansion space has a second size, and the second size is larger than the first size; and
a heating device, thermally coupled to the crucible.

2. The silicon carbide crystal expansion apparatus as recited in claim 1, wherein a material of the crucible includes graphite.

3. The silicon carbide crystal expansion apparatus as recited in claim 1, wherein a sidewall of the crystal expansion space is an arc slope.

4. The silicon carbide crystal expansion apparatus as recited in claim 1, wherein the crystal expansion space has an expanded thickness, a difference between the second size and the first size is an expanded size, and when the expanded thickness and the expanded size are in a same unit, a ratio of the expanded thickness to the expanded size is ¾˜ 5/4.

5. The silicon carbide crystal expansion apparatus as recited in claim 1, wherein a difference between the second size and the first size is an expanded size, and the expanded size is substantially 0.4 inches or 10 mm.

6. The silicon carbide crystal expansion apparatus as recited in claim 1, wherein:
the first size is greater than or substantially equal to 6 inches or 150 mm; or
the second size is less than or substantially equal to 8 inches or 200 mm.

7. The silicon carbide crystal expansion apparatus as recited in claim 1, wherein the main body comprises at least one heat-conductive rod extending upward from a bottom of the raw material space.

8. A silicon carbide crystal expansion method, comprising:
providing the silicon carbide crystal expansion apparatus as recited in claim 1;
placing the silicon carbide raw material in the raw material space;
placing a silicon carbide seed in the accommodating space; and
heating the crucible by the heating device, so that the silicon carbide raw material placed in the raw material space forming a silicon carbide and being disposed on the silicon carbide seed in the accommodating space.

9. The silicon carbide crystal expansion method as recited in claim 8, when the silicon carbide raw material placed in the raw material space forming the silicon carbide and being disposed on the silicon carbide seed in the accommodating space:
a pressure in the crucible is 0.5 torr to 30 torr;
a temperature inside the crucible is 2000C˜2500C;
a deposition rate of the silicon carbide is 100 m/hr˜200 m/hr; or
a temperature gradient of the silicon carbide raw material placed in the raw material space is less than or equal to 15 C.

10. A silicon carbide crystal expansion process, comprising:
performing a plurality times of the silicon carbide crystal expansion method as recited in claim 8 for expanding a 6-inch silicon carbide seed to 8 inches.
